(19) United States
(12) Patent Application Publication
(10) Pub. No.: US 2023/0092121 A1
(43) Pub. Date: Mar. 23, 2023

(54) SEMICONDUCTOR DEVICE

(71) Applicants: KABUSHIKI KAISHA TOSHIBA, TOKYO (JP); TOSHIBA ELECTRONIC DEVICES & STORAGE CORPORATION, tOKYO (JP)

(72) Inventors: Kakeru YAMAGUCHI, Yokohama (JP); Tetsuya YAMAMOTO, Sagamihara (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/898,536

(22) Filed: Aug. 30, 2022

(30) Foreign Application Priority Data
Sep. 22, 2021 (JP) 2021-154759

(51) Int. Cl. H01L 23/00; H01L 23/495

(52) U.S. Cl. CPC H01L 24/37; H01L 24/32; H01L 24/73; H01L 23/49568; H01L 23/49565; H01L 23/49562; H01L 2224/37147; H01L 2924/37001; H01L 2924/3512; H01L 2224/37005; H01L 2224/37011; H01L 2224/37013; H01L 2224/32245; H01L 2224/73101; H01L 2224/73151; H01L 2924/13091

(57) ABSTRACT

According to one embodiment, a semiconductor device includes a lead frame, a semiconductor chip, and a clip member. The semiconductor chip is mounted on the lead frame. The clip member is connected to an electrode of the semiconductor chip via a conductive adhesive agent. At least part of an outer peripheral edge of a connection face of the clip member is located at a position more inside than an outermost peripheral edge of the clip member in plan view.

### CROSS-REFERENCE TO RELATED APPLICATIONS

This application is based upon and claims the benefit of priority from Japanese Patent Application No. 2021-154759, filed on Sep. 22, 2021, the entire contents of which are incorporated herein by reference.

### FIELD

Embodiments described herein relate generally to a semiconductor device.

### BACKGROUND

There is a known semiconductor device in which a lead frame and electrodes of a semiconductor chip are electrically connected by, for example, plate-like connectors. Connections between the electrodes and the connectors, and connections between the lead frame and the connectors, are mechanically and electrically made by a conductive adhesive agent such as solder.

For a semiconductor package manufactured by, for example, bonding a silicon (Si) chip to a lead frame and copper (Cu) connectors with lead solder and performing mold sealing, a reflow furnace is used in the bonding process.

In a case where a sufficient clearance with a bonding face cannot be secured when a large-area copper connector is bonded to a silicon chip (semiconductor chip), there is a problem that a connection (bonding) failure or a solder fillet formation failure occurs and such a failure may cause a defective product from the viewpoint of reliability of the solder bonding portion.

### BRIEF DESCRIPTION OF THE DRAWINGS

FIG. 1 is an external perspective view of a semiconductor device before molding according to an embodiment;

FIG. 2 is a plan view of the main part of the semiconductor device before molding in the embodiment;

FIG. 3 is a plan view of a silicon chip;

FIG. 4 is an explanatory cross-sectional view of a soldering connection portion of a first electrode of the embodiment;

FIG. 5 is an enlarged view of a broken line circle C portion in FIG. 4 that corresponds to the first embodiment;

FIG. 6 is an explanatory graph of a measurement result of a copper clip movement amount;

FIG. 7 is an enlarged view of the broken line circle C portion in FIG. 4 that corresponds to a second embodiment; and

FIG. 8 is an enlarged view of the broken line circle C portion in FIG. 4 that corresponds to a third embodiment.

### DETAILED DESCRIPTION

According to one embodiment, a semiconductor device includes a lead frame, a semiconductor chip, and a clip member. The semiconductor chip is mounted on the lead frame. The clip member is connected to an electrode of the semiconductor chip via a conductive adhesive agent. At least part of an outer peripheral edge of a connection face of the clip member is located at a position more inside than an outermost peripheral edge of the clip member in plan view.

Next, embodiments will be described with reference to the drawings.

In the present specification, components according to embodiments and description of the components may be described in a plurality of expressions. The components and the description thereof are examples, and are not limited by the expressions in the present specification. The components may be identified with names different from those in the specification. In addition, the components may be described by an expression different from those in the specification.

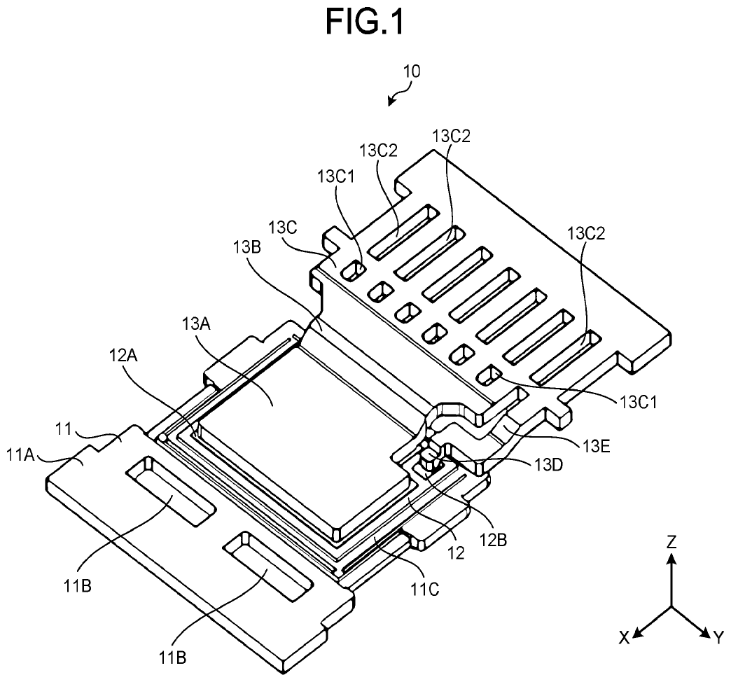

FIG. 1 is an external perspective view of a semiconductor device before molding according to an embodiment.

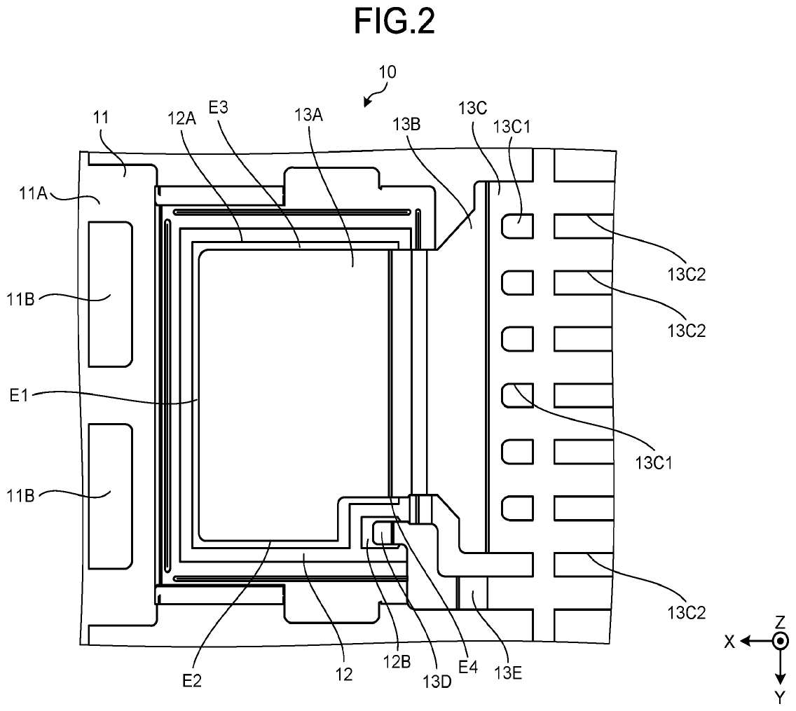

FIG. 2 is a plan view of the main part of the semiconductor device before molding in the embodiment.

A semiconductor device 10 is configured as, for example, a power device (power transistor). Note that the semiconductor device 10 is not limited to this example and may be another device.

As illustrated in FIG. 1, in the specification, an X axis, a Y axis, and a Z axis are defined for convenience. The X axis, the Y axis, and the Z axis are orthogonal to each other. The X axis is provided along the width of the semiconductor device 10. The Y axis is provided along the length (depth) of the semiconductor device 10. The Z axis is provided along the thickness of the semiconductor device 10.

Moreover, in the present specification, an X direction, a Y direction, and a Z direction are defined. The X direction is a direction along the X axis. The X direction includes a +X direction indicated by the arrow of the X axis and a −X direction which is a direction opposite to the arrow of the X axis. The Y direction is a direction along the Y axis. The Y direction includes a +Y direction indicated by the arrow of the Y axis and a −Y direction which is a direction opposite to the arrow of the Y axis. The Z direction is a direction along the Z axis. The Z direction includes a +Z direction indicated by the arrow of the Z axis and a −Z direction which is a direction opposite to the arrow of the Z axis.

As illustrated in FIG. 1, the semiconductor device 10 includes a lead frame 11, a silicon chip 12, and a copper clip 13.

In the above configuration, the lead frame 11 functions as a conductive member (electrode) and a thermally conductive member (heat dissipation member).

The silicon chip 12 is a so-called semiconductor chip.

Similarly to the lead frame 11, the copper clip 13 functions as a conductive member (electrode) and a thermally conductive member (heat dissipation member).

The lead frame 11 includes a plate portion 11A and a plurality of openings 11B. The plate portion 11A having a flat plate shape. The openings 11B are provided in the plate portion 11A and arranged in the Y axis direction. The rectangular openings 11B each has a rectangular shape whose longitudinal direction is the Y axis direction when viewed in a plan view (viewed in the −Z direction).

The openings 11B allow resin to enter at the time of molding and act on fixing of the mold resin.

Moreover, the lead frame 11 includes a bonding face 11C having a planar shape, to which an electrode of one face (a lower face in FIG. 1) of the silicon chip 12 is solder-bonded.

In FIG. 2, symbol E1 represents an end face in the +X direction included in an outer peripheral edge (outer peripheral face) of the copper clip 13 in plan view.

Symbol E2 represents an end face in the +Y direction included in the outer peripheral edge (outer peripheral face) of the copper clip 13.

Symbol E3 represents an end face in the −Y direction included in the outer peripheral edge (outer peripheral face) of the copper clip 13.

Symbol E4 represents an end face in the −X direction included in the outer peripheral edge (outer peripheral face) of the copper clip 13.

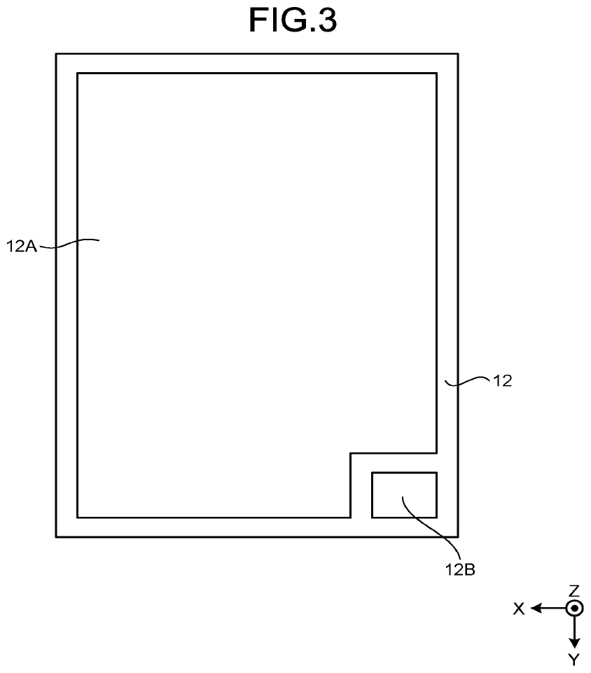

FIG. 3 is a plan view of the silicon chip.

On a top face (face directed in the +Z direction) of the silicon chip 12, a first electrode 12A and a second electrode 12B are provided.

The first electrode 12A has a substantially L-shape in which one corner of a rectangle is cut out into a rectangular shape.

The second electrode is provided at the position corresponding to the cutout portion of the first electrode 12A and has a rectangular shape.

The silicon chip 12 is, for example, a vertical device such as a vertical metal-oxide-semiconductor field effect transistor (MOSFET). The silicon chip 12 is not limited to this example and may be a vertical insulated gate bipolar transistor (IGBT), a vertical diode, or another semiconductor chip.

The silicon chip 12 contains silicon (Si) as a semiconductor. The semiconductor chip is not limited to the silicon chip 12 and may contain, for example, a compound semiconductor other than silicon, such as SiC or GaN.

In this case, for example, the first electrode 12A is configured as a drain electrode of a MOSFET for large current supply, and the second electrode 12B is configured as a drain electrode of a MOSFET for control.

The copper clip 13 is solder-connected to the first electrode 12A and the second electrode 12B.

As illustrated in FIGS. 1 and 2, the copper clip 13 includes a first connection portion 13A which is solder-connected to the first electrode 12A. Details of the soldering connection in the first electrode 12A will be described later.

With the above-described structure, the silicon chip 12 is mechanically fixed to the copper clip 13 to be in a predetermined heat conduction state and is able to dissipate heat through the copper clip 13.

An extending portion 13B extending in the −X direction and the +Z direction is connected consecutively to the first connection portion 13A.

Moreover, an external terminal portion 13C is continuously connected to the extending portion 13B.

The external terminal portion 13C includes a plurality of openings 13C1 arranged in the Y axis direction. Each of the opening 13C1 has a rectangular shape (substantially square shape) in plan view, into which the mold resin enters.

The external terminal portion 13C further includes a plurality of openings 13C2 arranged in parallel in the Y axis direction. Each of the openings 13C2 has a rectangular shape in plan view, whose longitudinal direction is the X axis direction.

The copper clip 13 includes a second connection portion 13D which is solder-connected to the second electrode 12B.

The second connection portion 13D is connected consecutively to an extending portion 13E that extends once in the −X direction, extends in the +Y direction, and then extends in the −X direction and the +Z direction to reach the external terminal portion 13C.

Therefore, the same potential is applied to the first electrode 12A and the second electrode 12B.

Next, details of soldering connection of the first electrode 12A will be described.

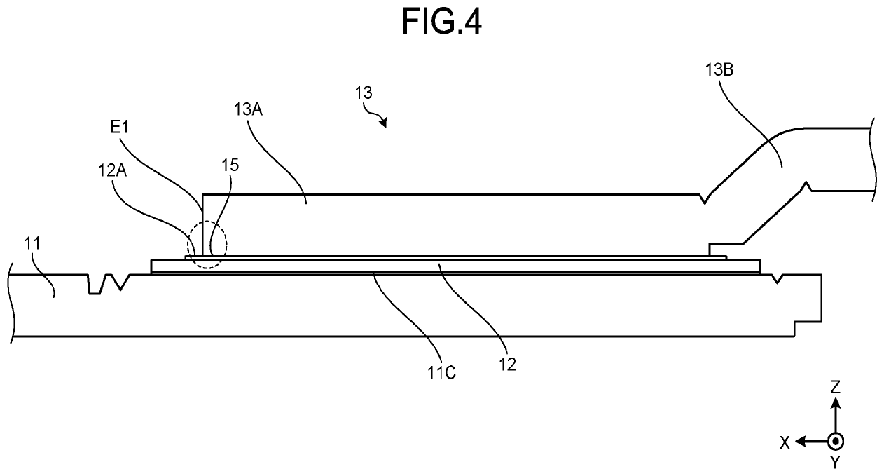

FIG. 4 is an explanatory cross-sectional view of a soldering connection portion of the first electrode of the embodiment.

In FIG. 4, to facilitate understanding, a portion corresponding to an end face E1 in the +X direction included in the outer peripheral edge (outer peripheral faces) of the copper clip 13 in plan view will be described as an example.

The silicon chip 12 is electrically and mechanically connected to the top face (face directed to the +Z direction) of the lead frame 11 via a solder layer 11C.

The first electrode 12A is formed on the top face (face in the +Z direction) of the silicon chip 12.

On the first electrode 12A, the first connection portion 13A is connected via a solder layer 15.

### 1. First Embodiment

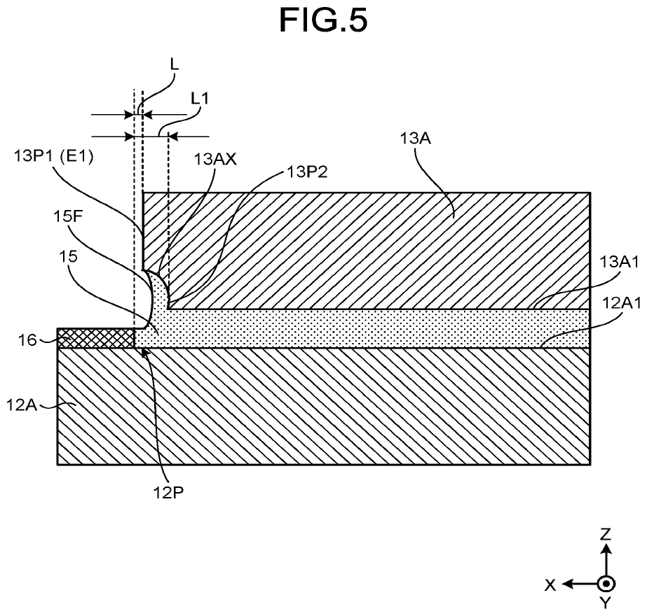

FIG. 5 is an enlarged view of the broken line circle C portion in FIG. 4 that corresponds to the first embodiment.

A non-conductive surface protection film 16 is provided at an end (in the example of FIG. 5, an end face in the +X direction) of a connection face 12A1 of the first electrode 12A.

The surface protection film 16 is formed of, for example, polyimide. The surface protection film 16 has low wettability to solder and inhibits formation of a solder fillet.

For this reason, if the first connection portion 13A is located at a position facing the surface protection film 16 or a position quite close to the surface protection film 16, no fillet of solder is formed, which may disadvantageously result in a solder connection failure and eventually a decrease in the product yield.

In the first embodiment, an outer peripheral edge 13P2, which is at least part of an outermost peripheral edge 13P1 of the connection face of the copper clip 13, is located at a position more inside (−X direction in the case of FIG. 5) than an outermost peripheral edge 13P1 of the copper clip 13 in plan view.

In this case, the outer peripheral edge 13P2, which is at least part of the outer peripheral edge of the connection face 13A of the copper clip 13, is positioned within a range of the connection face 12A1 of the first electrode 12A and is a predetermined distance L apart from the position of an outer peripheral edge 12P of the connection face 12A1 of the first electrode 12A.

Therefore, a cross section corresponding to the outer peripheral edge 13P2, which is at least part of the outer peripheral edge of the connection face 13A of the copper clip 13, has a shape in which a recess 13AX is formed.

That is, in the semiconductor device 10 according to the first embodiment, the cross-sectional shape of the copper clip 13 member is a shape cut out in a fan shape, as illustrated in FIG. 5.

The position of the outer peripheral edge 12P of the connection face 12A1 of the first electrode 12A is defined by the non-conductive surface protection film 16 made of polyimide.

Therefore, according to the first embodiment, it is possible to secure the clearance (corresponding to the distance L1) between the non-conductive surface protection film 16 and the copper clip 13 on the connection face 12A1 of the first electrode 12A, and possible to form a solder fillet 15F as illustrated in FIG. 5.

By the way, in a solder connection process of connecting the silicon chip 12 to the lead frame 11 and the copper clip 13 by using lead (Pb) solder, a reflow furnace is used in the manufacturing process from the viewpoint of improving manufacturing efficiency.

In this case, a solder fillet is formed at a tip of the copper clip 13 (that is, the end of the copper clip 13 in the +X direction in the example of FIG. 5). Thus, in the case of a conventional example in which the recess 13AX is not formed in the copper clip 13, the copper clip 13 moves significantly in the +X direction.

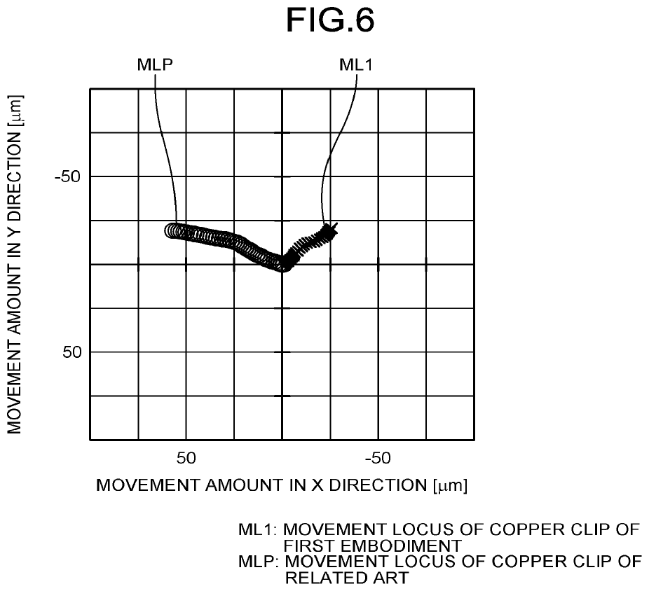

FIG. 6 is an explanatory graph of a measurement result of the copper clip movement amount.

In FIG. 6, symbol ML1 denotes a movement locus of the copper clip of the first embodiment during a reflow process.

On the other hand, symbol MLP in FIG. 6 denotes a movement locus of a copper clip of the related art during the reflow process.

In these cases, the origin position is the position of the copper clip before the reflow process.

As illustrated on the left side of FIG. 6, it can be seen that, in the case where the recess 13AX is not provided in the first connection portion 13A of the copper clip 13 (MLP), there is a movement in the X-axis direction 2.5 times larger than that in the case where the recess 13AX is provided in the first connection portion 13A of the copper clip 13 (ML1).

In other words, according to the present embodiment, even in a case where the distance to the formation position of the surface protection film 16 is short, it is possible to suppress the movement amount of the copper clip 13 and to reliably form the solder fillet 15F in the recess 13AX.

In the above description, the case where the recess 13AX is provided on the end face E1 in the +X direction of the copper clip 13 has been described. It is also possible to provide a recess similar to the recess 13AX on the end face E2 in the +Y direction, the end face E3 in the −Y direction, and the end face E4 in the −X direction of the copper clip 13.

In this case, the movement of the copper clip 13 during the process of the reflow furnace is canceled to some extent in the +Y direction and the −Y direction of the copper clip 13.

The movement amount in the +Y direction and the −Y direction is not so large even if the recess is not included. Thus, out of the end face E1 in the +X direction and the end face E4 in the −X direction of the copper clip 13, it is only required to provide a recess 13AY at least on the end face El.

As described above, according to the first embodiment, even in a case where the clearance (corresponding to the distance L) between the non-conductive surface protection film 16 and the copper clip 13 is small on the connection face 12A1 of the first electrode 12A, an effective clearance (corresponding to the distance L1) between the surface protection film 16 and the copper clip 13 can be secured, and thus the solder fillet 15F can be formed more reliably while suppressing the positional shift of the copper clip 13.

Therefore, according to the first embodiment, it is possible to avoid solder connection failures, to improve crack resistance, and to improve the product yield.

### 2. Second Embodiment

Next, a second embodiment will be described.

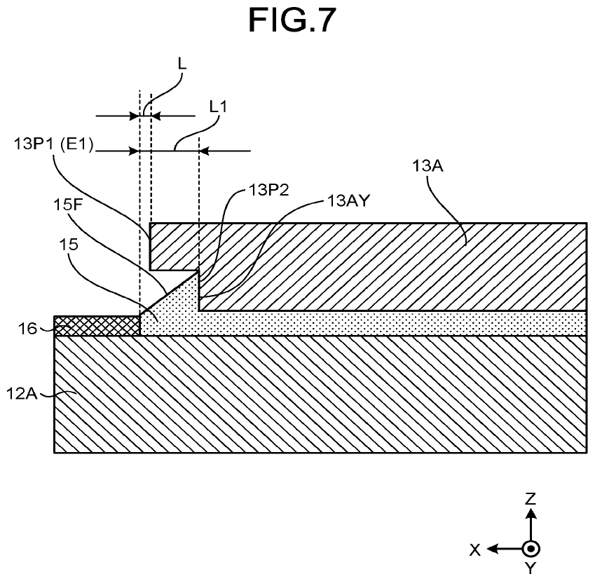

FIG. 7 is an enlarged view of the broken line circle C portion in FIG. 4 that corresponds to the second embodiment.

A non-conductive surface protection film 16 made of polyimide, for example, is provided at an end (in the example of FIG. 7, an end in the +X direction) of the connection face 12A1 of the first electrode 12A.

Therefore, also in the second embodiment, for the similar reason to that in the first embodiment, an outer peripheral edge 13P2, which is at least part of the outermost peripheral edge 13P1 of the connection face of the copper clip 13, is located at a position more inside (−X direction in the case of the example of FIG. 7) than the outer peripheral edge 13P1 of the copper clip 13 in plan view.

In this case, the distance to an end of the surface protection film 16, that is, an effective end of the connection face 12A1 of the first electrode 12A is L.

Moreover, with respect to the outermost peripheral edge 13P1 of the connection face 13A of the copper clip 13, the outer peripheral edge 13P2, which is at least part of the outer peripheral edge of the connection face 13A of the copper clip 13, is positioned within the range of the connection face 12A1 of the first electrode 12A and is a distance L1 (>L) apart from the position of the outer peripheral edge 12P of the connection face 12A1 of the first electrode 12A.

Therefore, a cross section corresponding to the outer peripheral edge 13P2, which is at least part of the outer peripheral edge of the connection face 13A of the copper clip 13, has a shape in which the recess 13AY is provided.

That is, in the semiconductor device 10 according to the second embodiment, the cross-sectional shape of the copper clip 13 member is a shape cut out in a rectangular (polygonal) shape, as illustrated in FIG. 7.

Therefore, according to the second embodiment, it is possible to secure the clearance (corresponding to the distance L1) between the non-conductive surface protection film 16 and the copper clip 13 on the connection face 12A1 of the first electrode 12A and to form the solder fillet 15F as illustrated in FIG. 7.

As a result, also in the second embodiment, it is possible to avoid solder connection failures, to improve crack resistance, and to improve the product yield.

In addition, since a solder fillet can be reliably formed by lead solder as a conductive adhesive agent, crack resistance can be improved.

### 3. Third Embodiment

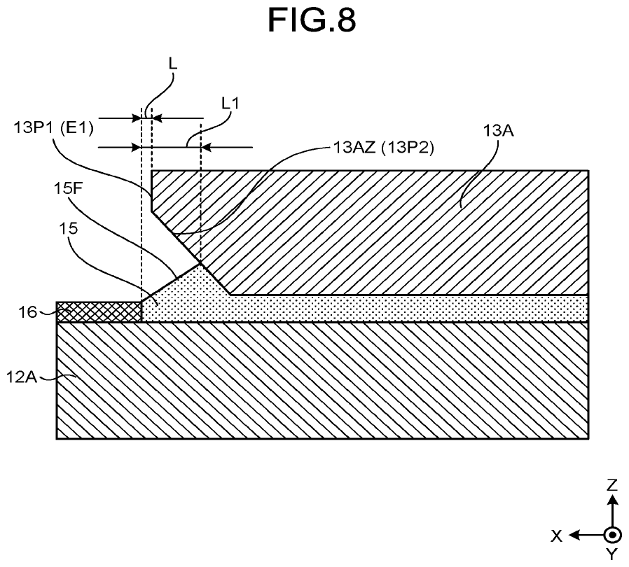

FIG. 8 is an enlarged view of the broken line circle C portion in FIG. 4 that corresponds to a third embodiment.

A non-conductive surface protection film 16 made of polyimide, for example, is provided at an end (end in the +X direction in the example of FIG. 8) of the connection face 12A1 of the first electrode 12A.

Therefore, also in the third embodiment, for a similar reason to those in the first and second embodiments, an effective position of an outer peripheral edge 13P2, which is at least part of the outermost peripheral edge 13P1 of the connection face of the copper clip 13, is located at a position more inside (−X direction in the case of the example of FIG. 8) than the outermost outer peripheral edge 13P1 of the copper clip 13 in plan view.

In this case, the distance to an end of the surface protection film 16, that is, an effective end of the connection face 12A1 of the first electrode 12A is L. Moreover, with respect to the outermost peripheral edge 13P1 of the connection face 13A of the copper clip 13, an effective position of the outer peripheral edge 13P2, which is at least part of the outer peripheral edge of the connection face 13A of the copper clip 13, that is, the effective position where a solder fillet is formed, is positioned within the range of the connection face 12A1 of the first electrode 12A and is a distance L1 (>L) apart from the position of the outer peripheral edge 12P of the connection face 12A1 of the first electrode 12A.

Therefore, a cross section corresponding to the outer peripheral edge 13P2, which is at least part of the outer peripheral edge of the connection face 13A of the copper clip 13, has a shape in which a recess 13AZ is provided.

That is, in the semiconductor device 10 according to the third embodiment, as illustrated in FIG. 8, the cross-sectional shape of the copper clip 13 member is a shape cut out in a triangular (polygonal) shape.

Therefore, according to the third embodiment, it is possible to secure the clearance (corresponding to the distance L1) between the non-conductive surface protection film 16 and the copper clip 13 on the connection face 12A1 of the first electrode 12A and to form the solder fillet 15F as illustrated in FIG. 8.

As a result, also in the third embodiment, it is possible to avoid solder connection failures, to improve crack resistance, and to improve the product yield.

In addition, a solder fillet can be reliably formed by lead solder as a conductive adhesive agent, so that crack resistance can be improved.

In the above description, the cross-sectional shape of the recess is a fan shape, a rectangular shape, or a triangular shape. Alternatively, for example, it is possible to cut out in a polygonal shape such as a square shape or a pentagonal shape.

In the description of the second and third embodiments above, the case where the recess 13AY or the recess 13AZ is provided on the end face E1 in the +X direction of the copper clip 13 has been described. It is also possible to include a recess similar to the recess 13AY or the recess 13AZ on the end face E2 in the +Y direction, the end face E3 in the −Y direction, and the end face E4 in the −X direction of the copper clip 13.

In this case, the movement of the copper clip 13 during the process of the reflow furnace is canceled to some extent in the +Y direction and the −Y direction of the copper clip 13.

For this reason, the movement amount in the +Y direction and the −Y direction is not so large even if the recess is not included. Therefore, it is only required to provide the recess 13AY or the recess 13AZ at least on the end face E1 out of the end face E1 in the +X direction and the end face E4 in the −X direction of the copper clip 13.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a lead frame;
a semiconductor chip mounted on the lead frame; and
a clip member connected to an electrode of the semiconductor chip via a conductive adhesive agent,
wherein at least part of an outer peripheral edge of a connection face of the clip member is located at a position more inside than an outermost peripheral edge of the clip member in plan view.

2. The semiconductor device according to claim 1, wherein the position of the at least part of the outer peripheral edge of the connection face of the clip member is located within a range of a connection face of the electrode and is a predetermined distance apart from an outer peripheral edge position of the connection face of the electrode.

3. The semiconductor device according to claim 2, wherein the outer peripheral edge position of the connection face of the electrode is defined by a non-conductive surface protection film.

4. The semiconductor device according to claim 1, wherein a cross-sectional shape corresponding to the at least part of the outer peripheral edge of the connection face of the clip member includes a recess at an end corresponding to the outer peripheral edge.

5. The semiconductor device according to claim 2, wherein a cross-sectional shape corresponding to the at least part of the outer peripheral edge of the connection face of the clip member includes a recess at an end corresponding to the outer peripheral edge.

6. The semiconductor device according to claim 3, wherein a cross-sectional shape corresponding to the at least part of the outer peripheral edge of the connection face of the clip member includes a recess at an end corresponding to the outer peripheral edge.

7. The semiconductor device according to claim 4, wherein the recess has a shape in which the cross-sectional shape of the clip member is cut out in a fan shape or a polygonal shape.

8. The semiconductor device according to claim 5, wherein the recess has a shape in which the cross-sectional shape of the clip member is cut out in a fan shape or a polygonal shape.

9. The semiconductor device according to claim 6, wherein the recess has a shape in which the cross-sectional shape of the clip member is cut out in a fan shape or a polygonal shape.
